(19) United States
(12) Patent Application Publication
(10) Pub. No.: US 2026/0156795 A1
(43) Pub. Date: Jun. 4, 2026

(54) Semiconductor layout pattern and manufacturing method thereof

(71) Applicant: UNITED MICROELECTRONICS CORP., Hsin-Chu City (TW)

(72) Inventors: Chun-Yen Tseng, Tainan City (TW); Chun-Hsien Huang, Tainan City (TW); Yu-Tse Kuo, Tainan City (TW); Shu-Ru Wang, Taichung City (TW); Chun-Hsien Lin, Tainan City (TW); Meng-Ping Chuang, Hsinchu City (TW)

(73) Assignee: UNITED MICROELECTRONICS CORP., Hsin-Chu City (TW)

(21) Appl. No.: 18/967,621

(22) Filed: Dec. 3, 2024

(30) Foreign Application Priority Data
Nov. 8, 2024 (TW) 113142895

(51) Int. Cl. H10B 10/00; G11C 15/04

(52) U.S. Cl. CPC H10B 10/12; G11C 15/04

(57) ABSTRACT

The invention provides a semiconductor layout pattern, which comprises a substrate, wherein two content addressable memory cells are disposed on the substrate and arranged on two sides of a symmetry axis, and a first matching line conductive layer and a second matching line conductive layer are located on the substrate, wherein from a top view, the first matching line conductive layer and the second matching line conductive layer overlap the symmetry axis between the two content addressable memory cells and are arranged along the direction of the symmetry axis.

### BACKGROUND OF THE INVENTION

### 1. Field of the Invention

The invention relates to the field of semiconductors, in particular to a layout pattern of a content addressable memory (CAM) and a manufacturing method thereof.

### 2. Description of the Prior Art

In General, when performing digital data operation, it is difficult to achieve real-time data query processing because of the huge amount of data to be processed, and the stored data of some applications (such as network routers) need to be dynamically updated in large quantities, and it is impossible to sort these stored data in advance. In order to speed up the search of these large and randomly stored data effectively, content addressable memory (CAM) is adopted to solve various search problems. Content addressable memory (also called associative memory) is like a huge lookup table, which can find out the address that matches the keyword according to the input keyword. The method is to use the special hardware architecture design of CAM, so that the keyword to be searched can be compared with the data stored in CAM at the same time, and the data address that matches the input keyword can be output, that is, the data related to the keyword can be found by using the keyword address found by CAM.

Content addressable memory can include binary CAM (BCAM) and ternary CAM (TCAM). Each bit in BCAM has two states, 0 or 1, while each bit in ternary state content addressable memory has three states. Besides 0 and 1, there is also a “don't care” state, so it is called ternary state. It is this ternary state feature of TCAM that enables it to perform both accurate matching and fuzzy matching search.

### SUMMARY OF THE INVENTION

The invention provides a semiconductor layout pattern, which comprises a substrate, wherein two content addressable memory (CAM) cells are on the substrate and arranged on two sides of a symmetry axis, and a first matching line (ML) conductive layer and a second matching line conductive layer are located on the substrate, wherein the first matching line conductive layer and the second matching line conductive layer overlap the symmetry axis between the two content addressable memory cells from a top view.

The invention also provides a method for manufacturing a semiconductor layout pattern, which comprises the following steps: providing a substrate, wherein two content addressable memory (CAM) cells are formed on the substrate and arranged on two sides of a symmetry axis, and a first matching line (ML) conductive layer and a second matching line conductive layer are formed on the substrate, wherein from a top view, the first matching line conductive layer and the second matching line conductive layer overlap the symmetry axis between the two content addressable memory cells and are arranged along the direction of the symmetry axis.

The invention is characterized by providing a layout pattern of a ten transistor cell and a corresponding circuit diagram. In another embodiment of the present invention, the conductive layers connecting the matching lines in each region are arranged to be aligned in the same direction, so as to reduce the number of wire structures passing through each region, and further, the regions can be arranged more closely to reduce the device area.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIG. 1 shows a circuit diagram of two adjacent ten transistor cells in a first embodiment of the present invention.

FIG. 2 shows the layout pattern of two adjacent ten transistor cells in the first embodiment of the present invention.

FIG. 3 is a schematic top view of a plurality of regions containing ten transistor cells and wires connecting matching lines according to the first embodiment of the present invention.

FIG. 4 shows the circuit diagram of two adjacent ten transistor cells in the second embodiment of the present invention.

FIGS. 5, FIG. 6 and FIG. 7 show the layout patterns of two adjacent ten transistor cells in the second embodiment of the present invention.

FIG. 8 is a schematic top view of a plurality of regions including ten transistor cells and wires connecting matching lines according to a second embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

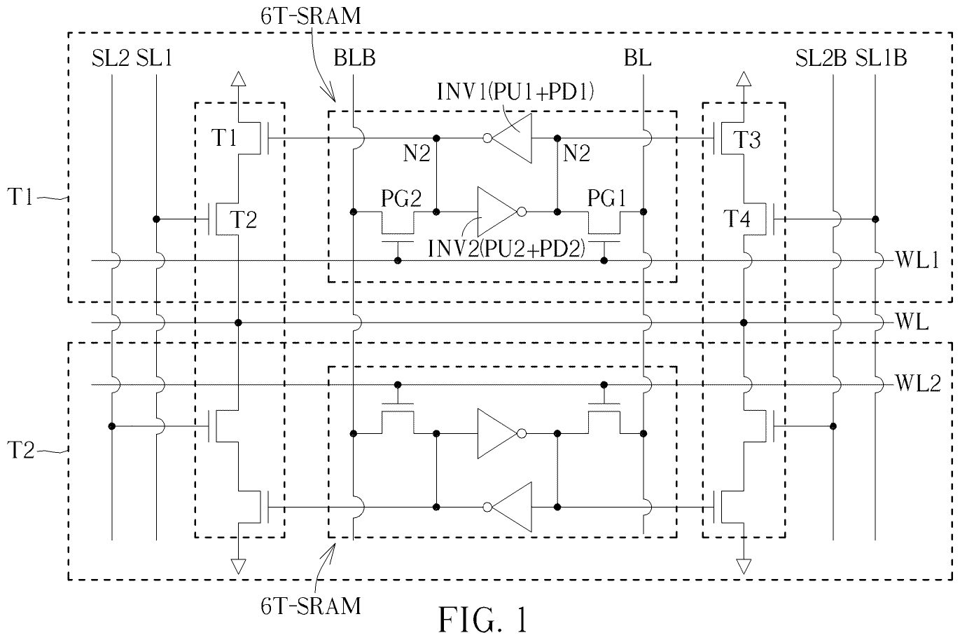

Please refer to FIG. 1, which shows the circuit diagram of two adjacent ten transistor cells in the first embodiment of the present invention. Please refer to FIG. 1 first. The region R1 in FIG. 1 is adjacent to the region R2. The region R1 in the upper half contains a ten transistor cell 1, and the region R2 in the lower half contains another ten transistor cell 2. In this embodiment, the ten transistor cell 1 or 2 can be applied to a content addressable memory (CAM) cell. In the following steps, the ten transistor cells 1 or 2 can be formed into a binary content addressable memory (BCAM) or a ternary content addressable memory (TCAM) as required. The following paragraphs mainly describe the ten transistor cell 1, and most elements of the ten transistor cell 2 are the same as those of the ten transistor cell 1, so they are not repeated here.

As shown in FIG. 1, The ten transistor cell 1 is composed of a first pull-up transistor PU1, a second pull-up transistor PU2, a first pull-down transistor PD1, a second pull-down transistor PD2, a first pass gate transistor PG1, a second pass gate transistor PG2, a first transistor T1 and a second transistor T2 connected in series, and a third transistor T1 and a fourth transistor T4 connected in series. The first pull-up transistor PU1 and the first pull-down transistor PD1 form a first inverter INV1, the second pull-up transistor PU2 and the second pull-down transistor PD2 form a second inverter INV2, and the first inverter INV1 and the second inverter INV2 form a latch circuit, so that data can be latched at storage node N1 and N2.

The first pull-up transistor PU1, the second pull-up transistor PU2, the first pull-down transistor PD1, the second pull-down transistor PD2, the first pass gate transistor PG1 and the second pass gate transistor PG2 together form a six transistor static random access memory (6T-SRAM). In addition, the first pull-up transistor PU1 and the second pull-up transistor PU2 are used as active loads, and they can also be used as pull-up elements instead of ordinary resistors, in this case, it is a four-transistor static random access memory (4T-SRAM). In addition, in this embodiment, a source region of each of the first pull-up transistor PU1 and the second pull-up transistor PU2 is electrically connected to a voltage source Vcc (not shown), and a source region of each of the first pull-down transistor PD1 and the second pull-down transistor PD2 is electrically connected to a voltage source Vss (not shown).

Generally speaking, the first pull-up transistor PU1 and the second pull-up transistor PU2 of a 6T-SRAM memory cell are composed of P-type metal oxide semiconductor (PMOS) transistors, while the first pull-down transistor PD1, the second pull-down transistor PD2, the first pass gate transistor PG1 and the second pass gate transistor PG2 are composed of N-type metal oxide semiconductor (N-type metal oxide semiconductor).

At the storage node N1, the gate G of the second pull-down transistor PD2, the gate G of the second pull-up transistor PU2, the drain D of the pull-down transistor PD1, the drain D first pull-up transistor PU1 and the drain D of the first pass gate transistor PG1 are respectively electrically connected. Similarly, at the storage node N2, the gate of the first pull-down transistor PD1, the gate of the first pull-up transistor PU1, and the drain of the second pull-down transistor PD2, the drain of the second pull-up transistor PU2 and the drain of the second pass gate transistor PG2 are respectively electrically connected. As for the gates of the first pass gate transistor PG1 and the second pass gate transistor PG2, they are respectively coupled to a word line WL1, while the source of the first pass gate transistor PG1 and the second pass gate transistor PG2 are respectively coupled to the corresponding bit line BL and bit line BLB.

As shown in FIG. 1, in this embodiment, the gate of the first transistor T1 is connected to the storage node N2 of the 6T-SRAM, that is, the gate of the first transistor T1 is connected to the gates of the first pull-up transistor PU1 and the first pull-down transistor PD1, and the drain of the first transistor T1 is connected to a voltage source (for example, the voltage source Vss). In addition, the second transistor T2 is connected in series with the first transistor T1, that is, the drain of the second transistor T2 is connected with the source of the first transistor T1. In addition, the gate of the second transistor T2 is connected to a search line SL1, and the source of the second transistor T2 is connected to a match line ML. On the other hand, the connection modes of the third transistor T3 and the fourth transistor T4 are similar and symmetrical to those of the first transistor T1 and the second transistor T2 respectively, wherein the gate of the third transistor T3 is connected to the storage node N1 of the 6T-SRAM, that is, the gate of the third transistor T3 is connected to the gates of the second pull-up transistor PU2 and the second pull-down transistor PD2, and the drain of the third transistor T3 is connected to a voltage source (for example, the voltage source Vss). In addition, the fourth transistor T4 is connected in series with the third transistor T3, that is, the drain of the fourth transistor T4 is connected with the source of the third transistor T3. In addition, the gate of the fourth transistor T4 is connected to the search line SLIB, and the source of the fourth transistor T4 is connected to the matching line ML.

The 6T-SRAM described above can be used as a unit for storing signals in the ternary content addressable memory (TCAM), while the first transistor T1, the second transistor T2, the third transistor T3 and the fourth transistor T4 connected with the 6T-SRAM are used as comparison logic circuits of the ternary content addressable memory. In other words, a ternary content addressable memory in this embodiment is composed of a 6T-SRAM and four other transistors.

In actual operation, the matching line ML can be pre-charge to a high potential, and then the search line SL1 and the search line SLIB are turned on or turned off with a high potential or a low potential, so as to compare the signals of the search lines SL1 and SLIB with the signals originally stored in the 6T-SRAM. For example, the high potential can be defined as signal 1, and the low potential can be defined as signal 0. According to different use requirements, the signals of the search line SL1 and the search line SLIB can be set to (0,1), (1,0) or (0,0), where the signal (0,1) or the signal (1,0) is compared with the signals of the storage nodes N1 and N2 stored in the 6T-SRAM. If the comparison results are consistent, the electric signal of the matching line ML will maintain a high potential; otherwise, if the comparison results are not consistent, the electric signal of the matching line ML will drop from a high potential to a low potential. In addition, the signal (0,0) represents the state of “don't care”, which can be used for fuzzy comparison. In a word, the ten transistor cell 1 according to the present invention can be used as a binary state content addressable memory (BCAM) or a ternary content addressable memory (TCAM) according to the use requirements, both of which are within the scope of the present invention. Other related technologies, such as the principle of content addressable memory and logical comparison method, are known in the field, and will not be described in detail in this paragraph.

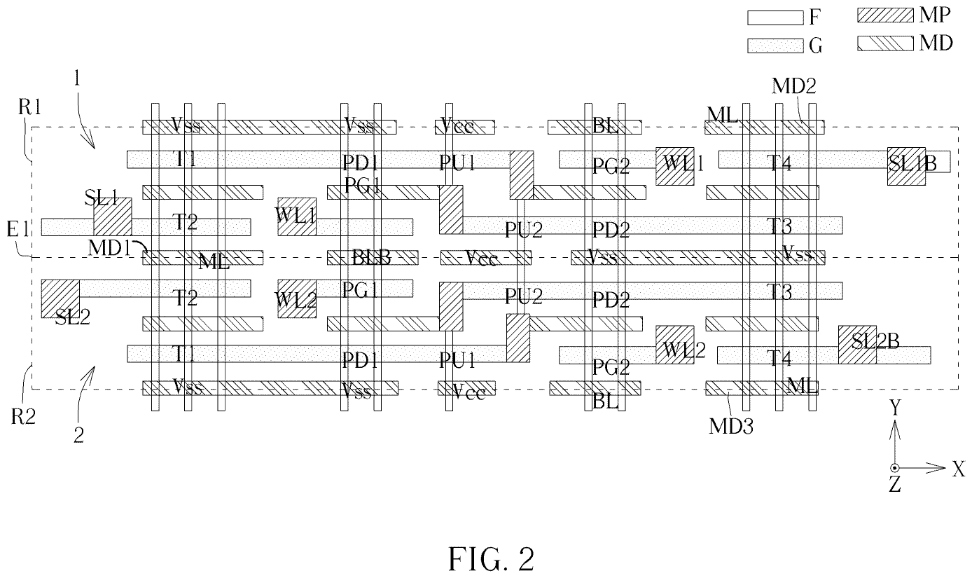

FIG. 2 shows the layout pattern of two adjacent ten transistor cells in the first embodiment of the present invention. As shown in FIG. 2, in order to form a ten transistor cell in each region, a plurality of fin structures F, a plurality of gate structures G (for example, but not limited to polysilicon gates) and a plurality of conductive layers are formed on a substrate 10. In FIG. 2, the conductive layers overlapping with the gate structure G are defined as MP, while the conductive layers not overlapping with the gate structure G are defined as MD, wherein the conductive layers MP and the conductive layers MD can be made of the same material, for example. Both the conductive layers MP and the conductive layers MD have the function of connecting elements. Therefore, in some embodiments, the conductive layers MP and the conductive layers MD can be regarded as the same layer structure.

In addition, the fin structure F can also be replaced by diffusion regions. However, in the following paragraphs, the fin structure F will still be described. The gate structure G spans the fin structure F and is combined into the transistors mentioned above, including a first pull-up transistor PU1, a second pull-up transistor PU2, a first pull-down transistor PD1, a second pull-down transistor PD2, a first pass gate transistor PG1, a second pass gate transistor PG2, a first transistor T1, a second transistor T2, a third transistor T3 and a fourth transistor T4. Each transistor can be electrically connected to various signal sources, such as bit lines BL/BLB, word lines WL1/WL2, search lines SL1/SL1B/SL2/SL2B, matching line ML, voltage source Vcc, voltage source Vss, etc., through subsequently formed metal wires or contact structures. For the sake of clear description of the drawings, in FIG. 2 and the layout of various embodiments of the present invention, the name of the transistor or the name of the connected signal source will be directly marked at the corresponding position in the layout to indicate that the position forms a specific transistor or that the position is connected to a specific signal source.

When two or more ten transistor cells 1 are arranged adjacent to each other, reference can be made to FIG. 1 and FIG. 2. The region R2 of the lower half of FIG. 1 includes a ten transistor cell 2, wherein the ten transistor cell 2 and the above-mentioned ten transistor cell 1 have circuit diagrams that are substantially symmetrical to each other. The difference is that the second transistor T2 in the ten transistor cell 2 is connected to the search line SL2, while the fourth transistor T4 in the ten transistor cell 2 is connected to the search line SL2B, and the gates of the first pass gate transistor PG1 and the second pass gate transistor PG2 in the ten transistor cell 2 are respectively coupled to the word line WL2. Except for the above elements, other elements of the ten transistor cell 2 and the elements of the ten transistor cell 1 are symmetrically arranged up and down along the matching line ML. In order to simplify the description, the elements of the symmetrical ten transistor cells 2 are not repeated.

It is worth noting that in the first embodiment of the present invention, as shown in FIGS. 1 and 2, the ten transistor cell 1 and the ten transistor cell 2 are connected to the same matching line ML. Therefore, if the conductive layer MD connecting the matching line ML can be arranged between the region R1 and the region R2 in the layout pattern, the ten transistor cells 1 and 2 can share the conductive layer MD connecting the matching line ML, and it is helpful for the layout and configuration of the devices.

However, the applicant found that the layout pattern of the first embodiment of the present invention still has room for improvement. More specifically, from the layout shown in FIG. 2, only a part of the conductive layer MD connecting the matching line ML is located on the edge line E1 between the region R1 and the region R2, while other conductive layers MD connecting the matching line ML are not located on the boundary line (the edge line E1) between the region R1 and the region R2. Specifically, the conductive layer connecting the matching line ML and located on the edge line E1 between the region R1 and the region R2 in FIG. 2 is defined as MD1, and the other two conductive layers are defined as MD2 and MD3. The conductive layer MD2 is located at the upper boundary of the region R1, and the conductive layer MD3 is located at the lower boundary of the region R2.

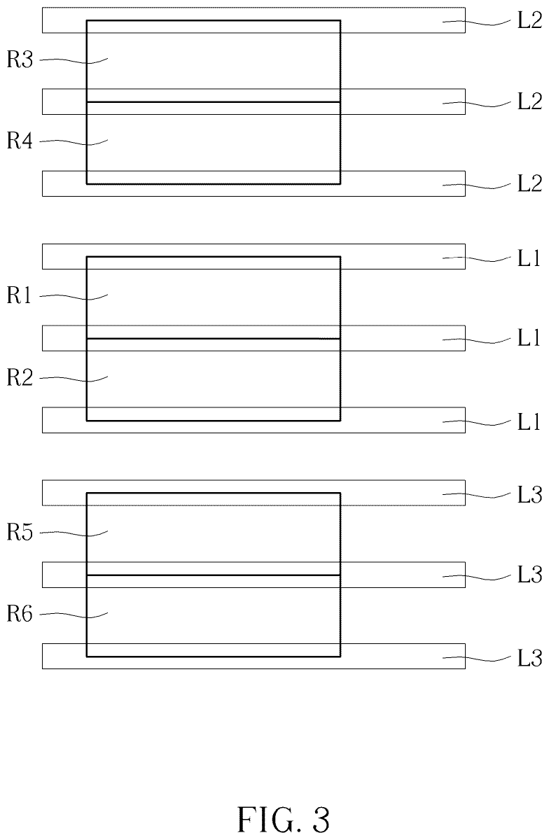

From the circuit diagram of FIG. 1, the conductive layer MD1, the conductive layer MD2 and the conductive layer MD3 are all connected to the same signal. Therefore, other wires need to be formed in the subsequent steps to connect the conductive layers MD1, MD2 and MD3 with each other. However, this configuration will occupy more component area and is not conducive to the miniaturization of components. Reference can be made to FIG. 3, which shows a schematic top view of a plurality of regions containing ten transistor cells and wires connecting matching lines according to the first embodiment of the present invention. As shown in FIG. 3, the substrate includes regions R1, R2, R3, R4, R5 and R6, wherein the region R1 is arranged adjacent to the region R2, and the wires electrically connected to the matching line ML are defined as wire structures L1, L2 and L3 respectively. The region R1 and the region R2 include three wire structures L1 extending in the lateral direction, wherein the three wire structures L1 are electrically connected with the conductive layers MD1, MD2 and MD3 in FIG. 2, and are electrically connected with the matching line ML, that is, the three wire structures L1 respectively pass through the upper boundary of the region R1, the boundary line between the region R1 and the region R2, and the lower boundary of the region R2. The region R1 and the region R2 described here are the same as the region containing ten transistor cells in the above-mentioned FIG. 2. In order to simplify the drawing, only the region and the wire structure are drawn here. Similarly, the remaining regions R3, R4, R5 and R6 and the wire structures L2 and L3 are also similar to the regions R1 and R2 and the wire structure L1 described above, so they are not repeated here.

It can be seen more clearly from FIG. 3 that when a plurality of regions containing ten transistor cells are arranged adjacent to each other, the layout pattern will be limited by the position of the wire structure, so that the regions cannot be closely arranged. For example, for region R1 and region R2, because the upper and lower boundaries respectively contain a wire structure L1, and the ten transistor cells in region R4 are connected to another matching line (corresponding wire structure L2), region R1 and region R4 cannot share the same wire structure. For example, in FIG. 3, the upper boundary of the region R1 contains the wire structure L1, and the lower boundary of the region R4 contains another wire structure L2, so a gap needs to be reserved between the upper boundary of the region R1 and the lower boundary of the region R4 to accommodate the two wire structures L1 and ML2 respectively. The above configuration has a large gap between regions, which is not conducive to miniaturization of components.

In order to improve the above problems, in another embodiment of the present invention, based on the modification of the above first embodiment, another ten transistor layout pattern and the corresponding circuit diagram are proposed. In another embodiment of the present invention, the conductive layers MD connecting the matching lines ML in each region are arranged to be aligned in the same direction, so as to reduce the number of wire structures passing through each region, so that each region can be arranged more closely to reduce the device area. See the following paragraphs for details.

In the following, different embodiments of the present invention will be described, and in order to simplify the description, the following description will mainly focus on the differences of each embodiment, and will not repeat the similarities. In addition, the same elements in various embodiments of the present invention are labeled with the same reference numerals, so as to facilitate the comparison among various embodiments.

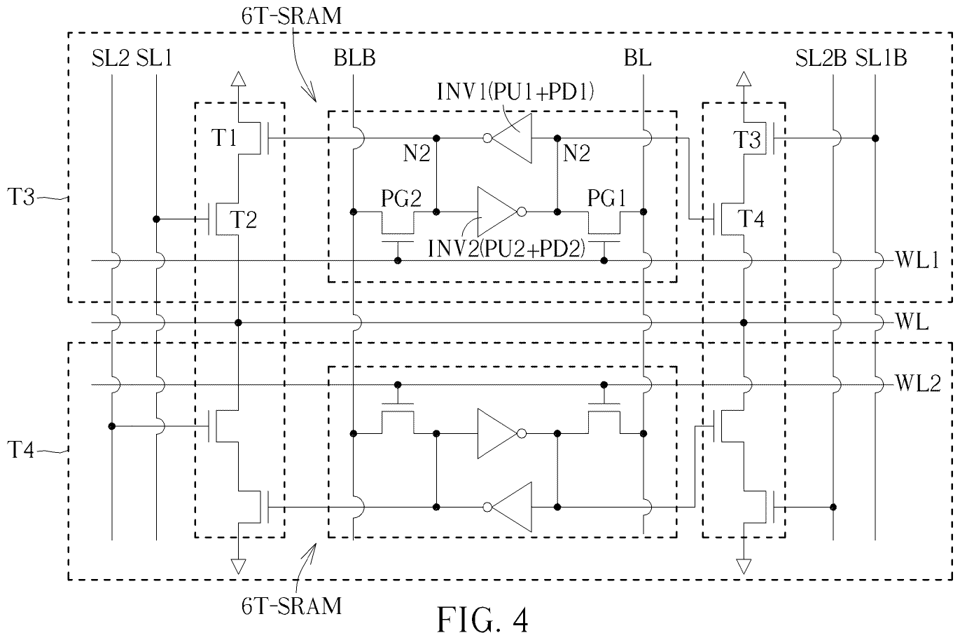

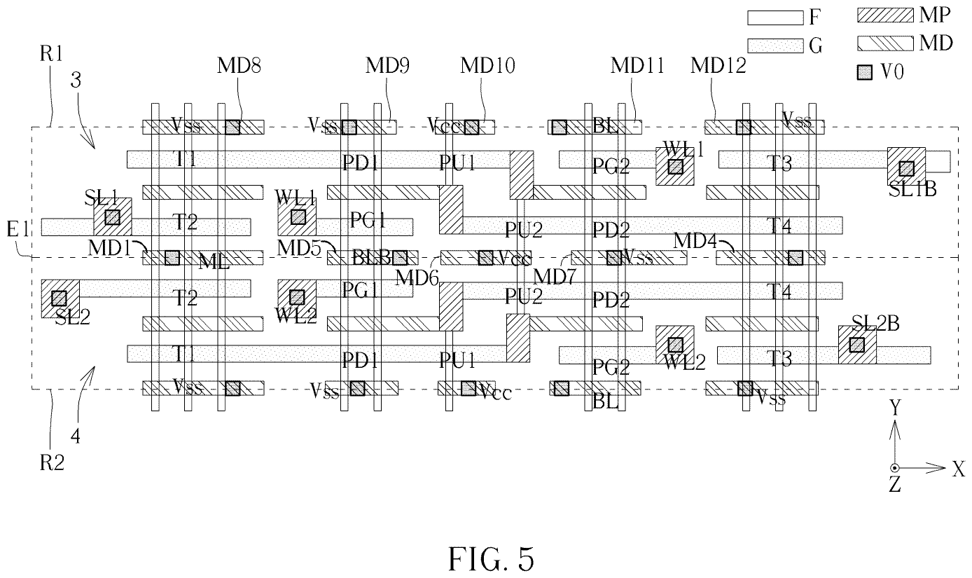

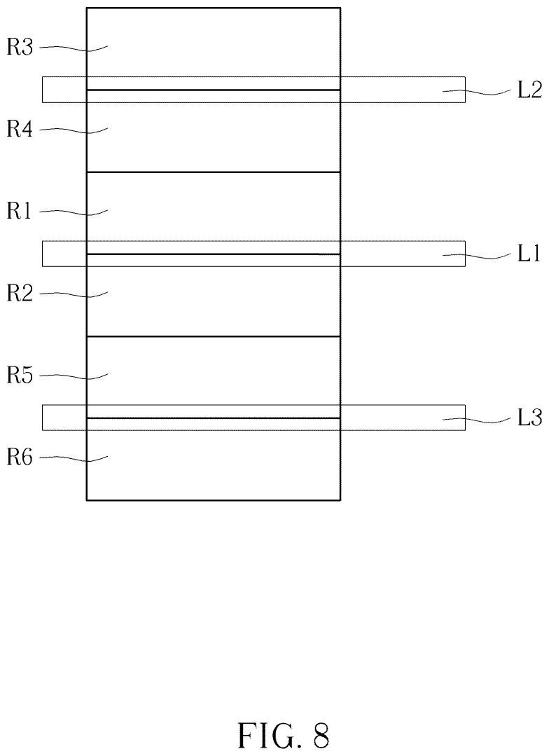

Please refer to FIGS. 4, 5, 6, 7 and 8. FIG. 4 shows the circuit diagram of two adjacent ten transistor cells in the second embodiment of the present invention. FIGS. 5, 6 and 7 show the layout pattern of two adjacent ten transistor cells in the second embodiment of the present invention. FIG. 8 shows a plurality of regions containing ten transistor cells and wires connecting matching lines according to the second embodiment of the present invention. In the above-mentioned first embodiment, the reason why the number of wire structures passing through each region is large is that the conductive layers MD1, MD2 and MD3 distributed in each region and connecting each matching line are not aligned in the same direction. In other words, in FIG. 2, the conductive layer MD1 is located on the edge line E1 between the region R1 and the region R2, but neither the conductive layers MD2 nor MD3 are located on the edge line E1 between the region R1 and the region R2. Therefore, in the second embodiment of the present invention, as shown in FIG. 5, the adjusted layout patterns of the ten transistor cells 3 and 4 are provided, wherein the main difference from the above-mentioned ten transistor cells 1 and 2 is that, in this embodiment, in the regions R1 and R2, all the conductive layers MD connecting the matching lines ML are located on the edge line E1 between the regions R1 and R2. In other words, for the region R1, except the edge line E1 (the lower boundary of the region R1), the other three boundaries (the left boundary, the upper boundary and the right boundary of the region R1 in FIG. 5) do not overlap with the conductive layer MD connecting the matching line ML. For the region R2, except the edge line E1 (the upper boundary of the region R2), the other three boundaries (the left boundary, the lower boundary and the right boundary of the region R2 in FIG. 5) do not overlap with the conductive layer MD connecting the matching line ML. More specifically, in this embodiment, the conductive layer connecting the matching line ML and the source of the second transistor T2 is defined as MD1, and the conductive layer connecting the matching line ML and the source of the fourth transistor T4 is defined as MD4, wherein both the conductive layer MD1 and the conductive layer MD4 are located on the edge line E1 between the region R1 and the region R2 and are aligned with each other in the X direction. Except the edge line E1, the other three boundaries of the region R1 and the region R2 do not contain the conductive layer MD connecting the matching line ML.

FIG. 5 contains a plurality of contact vias, these contact vias are defined as V0, wherein the main function of the contact vias is to connect elements of different layers, for example, to electrically connect the first metal layer M1, the first via V1, the second metal layer M2 and so on. Different from the above-mentioned conductive layers MP and MD, the contact via V0 and the first via V1 are usually used to connect elements of different layers in the vertical direction (Z direction), while the conductive layers MP and MD, the first metal layer M1 and the second metal layer M2 are used to connect different elements in the planar direction (XY plane).

Because the layout pattern is adjusted in this embodiment, the corresponding circuit diagram is also adjusted. Please refer to FIG. 4. The main difference between this embodiment and the above-mentioned first embodiment is that the line connection mode of the third transistor T4 and the fourth transistor T4 connected to the 6T-SRAM has changed. More specifically, in this embodiment, the gate of the fourth transistor T4 is connected to the storage node N1 of the 6T-SRAM, that is, the gate of the fourth transistor T4 is connected to the gates of the second pull-up transistor PU2 and the second pull-down transistor PD2, and the gate of the third transistor T3 is connected to the search line SL1B. Otherwise, the other circuit connections are basically the same as those shown in FIG. 1, including the drain of the third transistor T3 connected to a voltage source (for example, voltage source Vss), the fourth transistor T4 connected in series with the third transistor T3, and the source of the fourth transistor T4 connected to a matching line ML. Other unmentioned parts can refer to the above-mentioned first embodiment and the contents related to FIG. 1, and will not be repeated here.

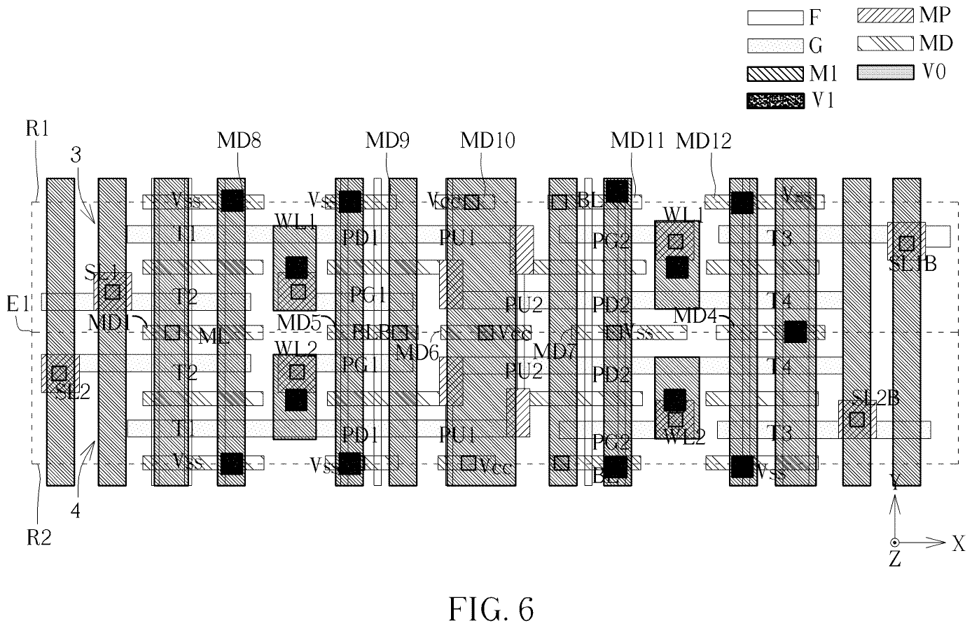

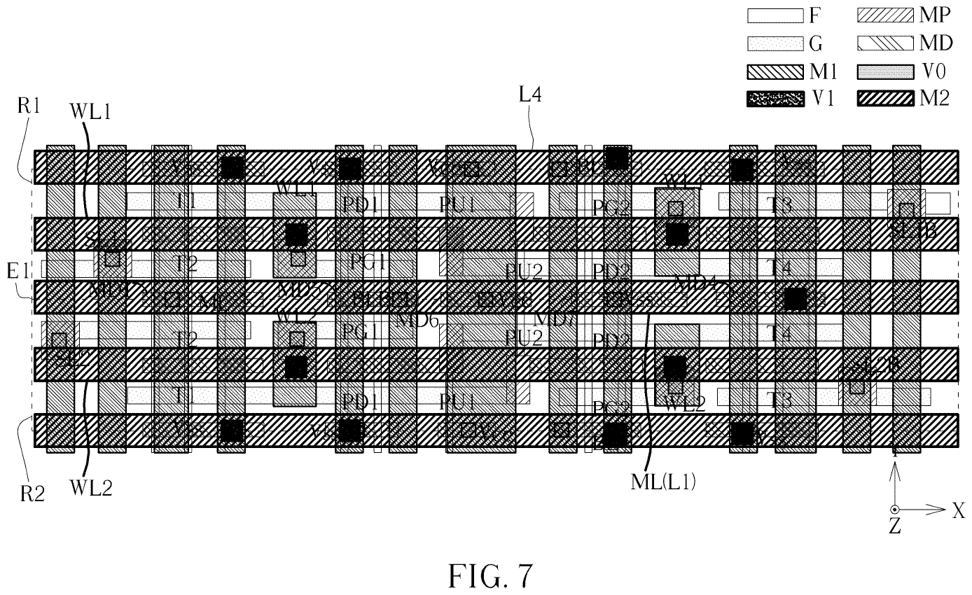

Subsequently, please continue to refer to FIGS. 6 and 7, and continue to form the first metal layer M1, the first via V1 and the second metal layer M2. To connect each element to different signal sources, such as bit lines BL/BLB, word lines WL1/WL2, search lines SL1/SL1B/SL2/SL2B, matching line ML, voltage source Vcc, voltage source Vss, etc. For the sake of clear description of the drawings, in FIGS. 6-7 and the layout drawings of various embodiments of the present invention, the names of transistors or connected signal sources are directly marked at the corresponding positions in the layout drawings, so as to indicate that the positions form a specific transistor or are connected to a specific signal source.

Notably, in this embodiment, the layout pattern of the ten transistor cell is adjusted so that all conductive layers (namely, the conductive layers MD1 and MD4) connected to the matching line ML are located on the edge line E1 between the region R1 and the region R2, and the number of conductive layers connected to the matching line ML is also reduced. For example, in FIG. 2, the region R1 and the region R2 include three conductive layers MD1, MD2 and MD3 connected to the matching line ML, but in the embodiment of FIG. 5, the region R1 and the region R2 include only two conductive layers MD1 and MD4 connected to the matching line ML.

Therefore, as shown in FIG. 7, after the second metal layer M2 is formed, the second metal layer M2 contains a plurality of metal lines (wire structure) parallel to each other along the X direction, and only one metal line is needed to electrically connect the conductive layers MD1 and MD4 in the region R1 and the region R2. Here, the second metal layer electrically connected to the matching line ML is defined as a wire structure L1, wherein the wire structure passes through the boundary line between the region R1 and the region R2, and the wire structure L1 in FIG. 7 is the same as that in FIG. 8.

For clearer explanation, FIG. 8 mainly depicts wire structures L1, L2, L3 and regions R1 to R6, and other elements are omitted. As shown in FIG. 8, when wire structures L1, L2 and L3 are formed to connect the conductive layers, it can be seen that the number of wire structures passing through each region and connecting the matching line ML will also decrease. For example, only one wire structure L1 needs to pass through the region R1 and the region R2 to connect the conductive layers MD1 and MD4 located in the region R1 and the region R2, and so on for other regions.

Therefore, as shown in FIG. 8, taking the region R1 and the region R4 as examples, the upper boundary of the region R1 does not include the wire structure, and the lower boundary of the opposite region R4 does not include the wire structure. Therefore, there is no need to reserve a space or gap between the region R1 and the region R4 to accommodate the wire structure. In this embodiment, the region R1 and the region R4 can be closely arranged (directly adjacent to each other). Compared with the embodiment shown in FIG. 3, this embodiment can reduce the total area of components.

Based on the above description and drawings, the present invention provides a semiconductor layout pattern, please refer to FIGS. 4-8, which includes a substrate 10 on which two content addressable memory (CAM) cells 3 and 4 are arranged on both sides of a symmetry axis (edge line E1). And a first matching line conductive layer (the conductive layer MD1 in FIG. 5) and a second matching line conductive layer (the conductive layer MD4 in FIG. 5) are located on the substrate, wherein from a top view, the first matching line conductive layer MD1 and the second matching line conductive layer MD4 overlap with a symmetry axis between the two content addressable memory cells and are arranged along the direction of the symmetry axis. In other words, the first matching line conductive layer MD1 and the second matching line conductive layer MD4 overlap the edge line E1 and are arranged along the direction of the edge line E1.

In some embodiments of the present invention, each content addressable memory cell includes four sides, one of which is the symmetry axis (the edge line E1), the other three sides except the symmetry axis are defined as outer boundaries, and the first matching line conductive layer MD1 and the second matching line conductive layer MD4 do not overlap with the three outer boundaries.

In some embodiments of the present invention, each content addressable memory cell includes ten transistor layout patterns, and each ten transistor layout pattern includes a first pull-up transistor (PU1) and a first pull-down transistor (PD1) to form a first inverter (INV1), a second pull-up transistor (PU2) and a second pull-down transistor (PD2) to form a second inverter (INV2). A first pass gate transistor (PG1) and a second pass gate transistor (PG2) are connected to the first inverter and the second inverter, and a first transistor T1 and a second transistor T2 are connected in series, wherein the gate structure of the first transistor T1 is connected to the gate structure of the first pull-down transistor (PD1), and a third transistor T3 and a fourth transistor T4 are connected in series, wherein the gate structure of the fourth transistor T4 is connected to the second pull-down.

In some embodiments of the present invention, a gate of the second transistor T2 and a gate of the third transistor T3 are respectively connected to a search line SL1 and a search line SL1B.

In some embodiments of the present invention, a source of the second transistor T2 and a source of the fourth transistor T4 are connected to a matching line ML.

In some embodiments of the present invention, a drain of the first transistor T1 and a drain of the third transistor T3 are connected to a voltage source (Vss).

In some embodiments of the present invention, as seen from the top view, along a horizontal direction, the symmetry axis E1 between two content addressable memory cells sequentially includes a first matching line conductive layer (the conductive layer MD1 in FIG. 5), a bit line conductive layer (the conductive layer MD5 in FIG. 5), a Vcc voltage source conductive layer (the conductive layer MD6 in FIG. 5), a Vss voltage source conductive layer (the conductive layer MD7 in FIG. 5) and a second matching line conductive layer (the conductive layer MD4 in FIG. 5).

In some embodiments of the present invention, a second metal layer M2 is further included, in which the second metal layer comprises a first part (i.e., the wire structure L1 connecting the conductive layer MD1 and the conductive layer MD4 in FIG. 7), and the first part is a strip pattern extending along the horizontal direction, and the first part is electrically connected with the first matching line conductive layer MD1 and the second matching line conductive layer MD4.

In some embodiments of the present invention, one of the two content addressable memory cells includes an upper boundary, wherein along a horizontal direction, The upper boundary of the content addressable memory cell sequentially includes a first Vss voltage source conductive layer (the conductive layer MD8 in FIG. 5), a second Vss voltage source conductive layer (the conductive layer MD9 in FIG. 5), a Vcc voltage source conductive layer (the conductive layer MD10 in FIG. 5), a bit line conductive layer (the conductive layer MD11 in FIG. 5), and a third Vss voltage source conductive layer (the conductive layer MD9 in FIG. 5)

In some embodiments of the present invention, the second metal layer M2 includes a second part (please refer to FIGS. 5 and 7, in which the wire structure L4 of the second metal layer M2 is located at the upper boundary), and the second part is a strip pattern extending in the horizontal direction and overlapping with the upper boundary, wherein the second part is electrically connected with the first Vss voltage source conductive layer MD8, the second Vss voltage source conductive layer MD9 and the third Vss voltage source conductive layer MD12.

The present invention also provides a method for manufacturing a semiconductor layout pattern, referring to FIGS. 4-8, which comprises providing a substrate 10, on which two content addressable memory (CAM) cells 3 and 4 are formed, which are arranged on both sides of the symmetry axis (the edge line E1). And forming a first matching line conductive layer (MD1 in FIG. 5) and a second matching line conductive layer (MD4 in FIG. 5) on the substrate, wherein from a top view, the first matching line conductive layer MD1 and the second matching line conductive layer MD4 overlap with the symmetry axis between the two content addressable memory cells and are arranged along the direction of the symmetry axis. In other words, the first matching line conductive layer MD1 and the second matching line conductive layer MD4 overlap the edge line E1 and are arranged along the direction of the edge line E1.

The invention is characterized by providing a layout pattern of a ten transistor cell and a corresponding circuit diagram. In another embodiment of the present invention, the conductive layers connecting the matching lines in each region are arranged to be aligned in the same direction, so as to reduce the number of wire structures passing through each region, and further, the regions can be arranged more closely to reduce the device area.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor layout pattern comprising:
a substrate;
two content addressable memory (CAM) cells arranged on both sides of a symmetry axis on the substrate; and
a first matching line (ML) conductive layer and a second matching line conductive layer located on the substrate, wherein from a top view, the first matching line conductive layer and the second matching line conductive layer overlap with the symmetry axis between the two content addressable memory cells, and are arranged along the direction of the symmetry axis.

2. The conductor layout pattern according to claim 1, wherein each of the content addressable memory cells comprises four sides, one of the four sides is the symmetry axis, the other three sides except the symmetry axis are defined as outer boundaries, and the first matching line conductive layer and the second matching line conductive layer do not overlap with the three outer boundaries.

3. The conductor layout pattern according to claim 1, wherein each content addressable memory cell comprises ten transistor layout patterns, and each ten transistor layout pattern comprises:
a first pull-up transistor (PU1) and a first pull-down transistor (PD1) form a first inverter (INV1), a second pull-up transistor (PU2) and a second pull-down transistor (PD2) form a second inverter (INV2);
a first pass gate transistor (PG1) and a second pass gate transistor (PG2) connect the first inverter and the second inverter; and
a first transistor and a second transistor connected in series with each other, wherein the gate structure of the first transistor is connected with the gate structure of the first pull-down transistor (PD1); and
a third transistor and a fourth transistor connected in series with each other, wherein the gate structure of the fourth transistor is connected with the gate structure of the second pull-down transistor (PD2).

4. The conductor layout pattern according to claim 3, wherein a gate of the second transistor and a gate of the third transistor are respectively connected to a search line SL1 and another search line SL1B.

5. The conductor layout pattern according to claim 3, wherein a source of the second transistor and a source of the fourth transistor are connected to a matching line (ML).

6. The conductor layout pattern according to claim 3, wherein a drain of the first transistor and a drain of the third transistor are connected to a voltage source (Vss).

7. The conductor layout pattern according to claim 1, wherein the first matching line conductive layer, a bit line conductive layer, a Vcc voltage source conductive layer, a Vss voltage source conductive layer, and the second matching line conductive layer are sequentially included on the symmetrical axis between the two content addressable memory cells along a horizontal direction.

8. The conductor layout pattern according to claim 1, further comprising a second metal layer, wherein the second metal layer comprises a first part which is a strip pattern extending along the horizontal direction, and the first part is electrically connected with the first matching line conductive layer and the second matching line conductive layer.

9. The conductor layout pattern according to claim 8, wherein one of the two content addressable memory cells includes an upper boundary, wherein the upper boundary of the content addressable memory cell sequentially includes a first Vss voltage source conductive layer, a second Vss voltage source conductive layer, a Vcc voltage source conductive layer, a bit line conductive layer, and a third Vss voltage source conductive layer along a horizontal direction.

10. The conductor layout pattern according to claim 9, wherein the second metal layer comprises a second part, which is a strip pattern extending in the horizontal direction and overlapping with the upper boundary, wherein the second part is electrically connected with the first Vss voltage source conductive layer, the second Vss voltage source conductive layer and the third Vss voltage source conductive layer.

11. A method for manufacturing a semiconductor layout pattern, comprising:
providing a substrate, wherein two content addressable memory (CAM) cells are formed on the substrate and arranged at two sides of a symmetry axis; and
forming a first matching line (ML) conductive layer and a second matching line conductive layer on the substrate, wherein from a top view, the first matching line conductive layer and the second matching line conductive layer overlap with the symmetry axis between the two content addressable memory cells and are arranged along the direction of the symmetry axis.

12. The manufacturing method of conductor layout pattern according to claim 11, wherein each of the content addressable memory cells comprises four sides, one of the four sides is the symmetry axis, the other three sides except the symmetry axis are defined as outer boundaries, and the first matching line conductive layer and the second matching line conductive layer do not overlap with the three outer boundaries.

13. The manufacturing method of conductor layout pattern according to claim 11, wherein each content addressable memory cell comprises ten transistor layout patterns, and each ten transistor layout pattern comprises:
a first pull-up transistor (PU1) and a first pull-down transistor (PD1) form a first inverter (INV1), a second pull-up transistor (PU2) and a second pull-down transistor (PD2) form a second inverter (INV2);
a first pass gate transistor (PG1) and a second pass gate transistor (PG2) connect the first inverter and the second inverter; and
a first transistor and a second transistor connected in series with each other, wherein the gate structure of the first transistor is connected with the gate structure of the first pull-down transistor (PD1); and
a third transistor and a fourth transistor connected in series with each other, wherein the gate structure of the fourth transistor is connected with the gate structure of the second pull-down transistor (PD2).

14. The manufacturing method of conductor layout pattern according to claim 13, wherein a gate of the second transistor and a gate of the third transistor are respectively connected to a search line SL1 and another search line SL1B.

15. The manufacturing method of conductor layout pattern according to claim 13, wherein a source of the second transistor and a source of the fourth transistor are connected to a matching line (ML).

16. The manufacturing method of conductor layout pattern according to claim 11, wherein a drain of the first transistor and a drain of the third transistor are connected to a voltage source (Vss).

17. The manufacturing method of the conductor layout pattern according to claim 11, wherein the first matching line conductive layer, a bit line conductive layer, a Vcc voltage source conductive layer, a Vss voltage source conductive layer, and the second matching line conductive layer are sequentially included on the symmetrical axis between the two content addressable memory cells along a horizontal direction.

18. The manufacturing method of conductor layout pattern according to claim 11, further comprising forming a second metal layer, wherein the second metal layer comprises a first part which is a strip pattern extending in the horizontal direction, and the first part is electrically connected with the first matching line conductive layer and the second matching line conductive layer.

19. The manufacturing method of conductor layout pattern according to claim 18, wherein one of the two content addressable memory cells includes an upper boundary, wherein the upper boundary of the content addressable memory cell sequentially includes a first Vss voltage source conductive layer, a second Vss voltage source conductive layer, a Vcc voltage source conductive layer, a bit line conductive layer, and a third Vss voltage source conductive layer along a horizontal direction.

20. The manufacturing method of conductor layout pattern according to claim 19, wherein the second metal layer comprises a second part, which is a strip pattern extending in the horizontal direction and overlapping with the upper boundary, wherein the second part is electrically connected with the first Vss voltage source conductive layer, the second Vss voltage source conductive layer and the third Vss voltage source conductive layer.
